(19) United States
(12) Patent Application Publication
(10) Pub. No.: US 2020/0135631 A1
(43) Pub. Date: Apr. 30, 2020

(54) SEMICONDUCTOR PACKAGE

(71) Applicant: SAMSUNG ELECTRONICS CO., LTD., Suwon-si (KR)

(72) Inventors: Young Kwan SEO, Suwon-si (KR); Seung Hun CHAE, Suwon-si (KR); So Yeon MOON, Suwon-si (KR)

(73) Assignee: SAMSUNG ELECTRONICS CO., LTD., Suwon-si (KR)

(21) Appl. No.: 16/661,585

(22) Filed: Oct. 23, 2019

(30) Foreign Application Priority Data
Oct. 26, 2018 (KR) 10-2018-0129208

(51) Int. Cl. H01L 23/498; H01L 23/31; H01L 23/053

(52) U.S. Cl. CPC H01L 23/49838; H01L 23/053; H01L 23/49822; H01L 23/3128

(57) ABSTRACT

A semiconductor package includes a semiconductor chip having a connection pad; an encapsulant covering at least a portion of the semiconductor chip; and an interconnect structure disposed on the semiconductor chip and the encapsulant. The interconnect structure includes a first insulating layer, a first redistribution layer disposed on the first insulating layer, and a second insulating layer disposed on the first insulating layer and covering the first redistribution layer, the first redistribution layer is electrically connected to the connection pad, and when a thickness of the first redistribution layer is a, and a gap between patterns of the first redistribution layer is b, b/a is 4 or less.

### CROSS-REFERENCE TO RELATED APPLICATION(S)

This application claims benefit of priority to Korean Patent Application No. 10-2018-0129208 filed on Oct. 26, 2018 in the Korean Intellectual Property Office, the disclosure of which is incorporated herein by reference in its entirety.

### BACKGROUND

The present disclosure relates to a semiconductor package, more particularly to a fan-out semiconductor package.

One of main trends in the field of semiconductor technology is to reduce the sizes of components, and it has been necessary to implement a plurality of fins having reduced sizes in accordance with an increase in consumption of small-sized semiconductor chips in the field of package development. To satisfy the demand, a fan-out semiconductor package has been developed. In a fan-out semiconductor package, connection pads may be redistributed to a region beyond a region in which semiconductor chips are disposed such that semiconductor chips may have reduced sizes and a plurality of fins may be implemented.

A vacuum lamination process used in the process of manufacturing a printed circuit board may effectively respond to a difference in thickness at each position as an insulating layer is formed by transition of the insulating layer to a substrate through vacuum lamination, but it is highly likely that a void may be formed due to defects caused by foreign objects created during cutting a film and a defect of incomplete filling of an insulating layer. Accordingly, in the field of a semiconductor package, a method of coating a substrate with a liquid insulating material has been used as a method for forming an insulating layer for forming a redistribution layer.

However, when the coating method is applied, a substrate may be coated along a pattern shape, which may cause an undulation phenomenon in which there may be a difference between a thickness of an insulating layer in a region covering a pattern already formed on a substrate, and a thickness of an insulting layer between patterns. If the undulation increases, insulating reliability may degrade.

### SUMMARY

An aspect of the present disclosure is to provide a semiconductor package capable of controlling undulation even when a coating method is applied when manufacturing an interconnect structure, a redistribution region of a semiconductor package.

According to an aspect of the present disclosure, a thickness of a redistribution layer and a thickness of an insulating layer between patterns may be controlled to satisfy a specific parameter when an interconnect structure, a redistribution region, is manufactured.

According to an aspect of the present disclosure, a semiconductor package includes a semiconductor chip having a connection pad; an encapsulant covering at least a portion of the semiconductor chip; and an interconnect structure disposed on the semiconductor chip and the encapsulant. The interconnect structure includes a first insulating layer, a first redistribution layer disposed on the first insulating layer, and a second insulating layer disposed on the first insulating layer and covering the first redistribution layer, the first redistribution layer is electrically connected to the connection pad, and when a thickness of the first redistribution layer is a, and a gap between patterns of the first redistribution layer is b, b/a is 4 or less.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram illustrating an example of an electronic device system;

FIG. 2 is a schematic perspective diagram illustrating an example of an electronic device;

FIGS. 3A and 3B are schematic cross-sectional diagrams illustrating states of a fan-in semiconductor package before and after a packaging process;

FIG. 4 is a schematic cross-sectional diagram illustrating a process of packaging a fan-in semiconductor package;

FIG. 5 is a schematic cross-sectional diagram illustrating an example in which a fan-in semiconductor package is mounted on a printed circuit board and mounted on a mainboard of an electronic device;

FIG. 6 is a schematic cross-sectional diagram illustrating an example in which a fan-in semiconductor package is mounted in a printed circuit board and mounted on a mainboard of an electronic device;

FIG. 7 is a schematic cross-sectional diagram illustrating a fan-out semiconductor package;

FIG. 8 is a schematic cross-sectional diagram illustrating an example in which a fan-out semiconductor package is mounted on a mainboard of an electronic device;

FIG. 9 is a schematic cross-sectional diagram illustrating an example of a semiconductor package;

FIG. 10 is an enlarged schematic cross-sectional diagram illustrating region A illustrated in FIG. 9; and

FIG. 11 is a schematic diagram illustrating another example of a semiconductor package.

### DETAILED DESCRIPTION

Hereinafter, example embodiments of the present disclosure will be described with reference to the accompanying drawings. In the drawings, shapes, sizes, and the like, of elements may be exaggerated or briefly illustrated for clarity of description.

Electronic Device

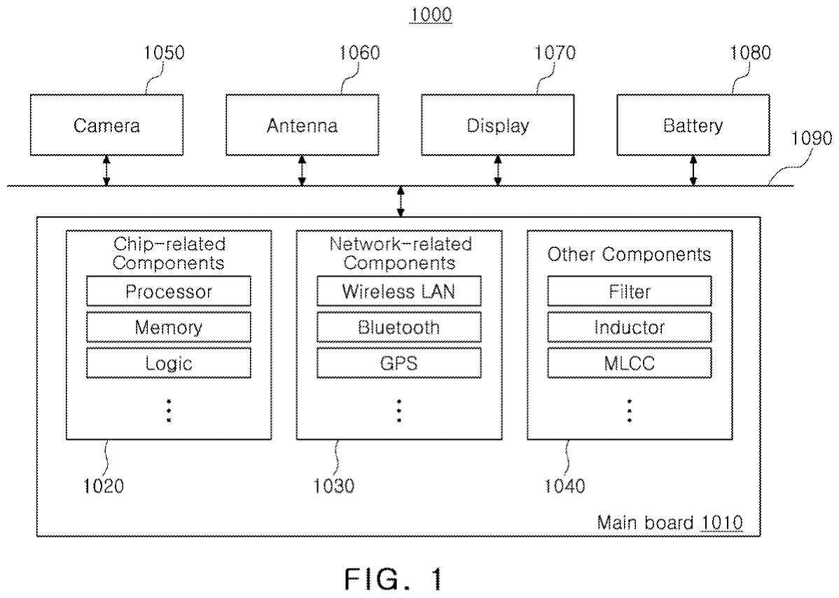

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

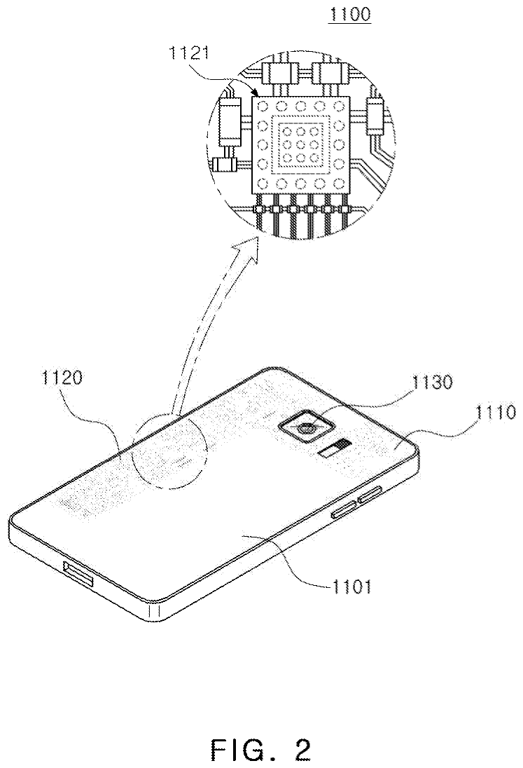

FIG. 2 is a schematic perspective diagram illustrating an example of an electronic device.

Referring to FIG. 2, a semiconductor package may be used for various purposes in the various electronic devices 1000 as described above. For example, a motherboard 1110 may be accommodated in a body 1101 of a smartphone 1100, and various electronic components 1120 may be physically or electrically connected to the motherboard 1110. In addition, other components that may or may not be physically or electrically connected to the motherboard 1110, such as a camera module 1130, may be accommodated in the body 1101. Some of the electronic components 1120 may be the chip related components, for example, a semiconductor package 1121, but are not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will be described in greater detail with reference to the drawings.

Fan-In Semiconductor Package

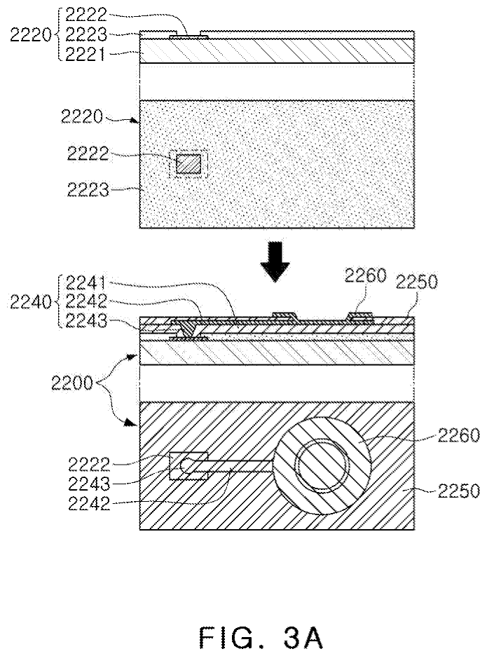

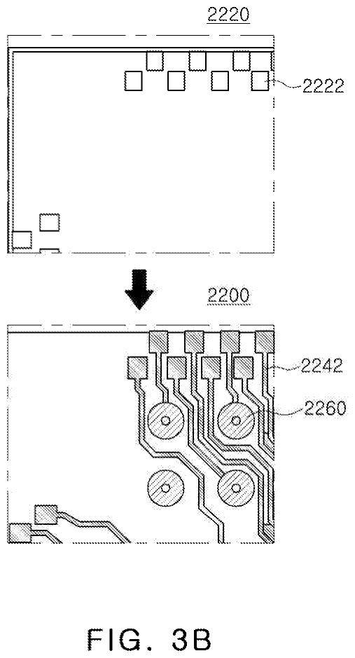

FIGS. 3A and 3B are schematic cross-sectional diagrams illustrating states of a fan-in semiconductor package before and after a packaging process.

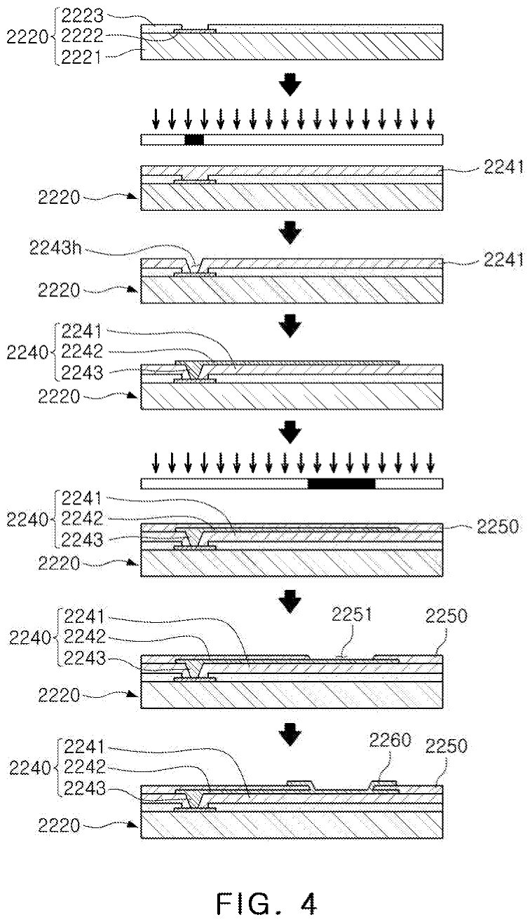

FIG. 4 is a schematic cross-sectional diagram illustrating a process of packaging a fan-in semiconductor package.

Referring to the diagrams, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide layer, a nitride layer, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even though a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip are not enough to directly mount the fan-in semiconductor package on the mainboard of the electronic device.

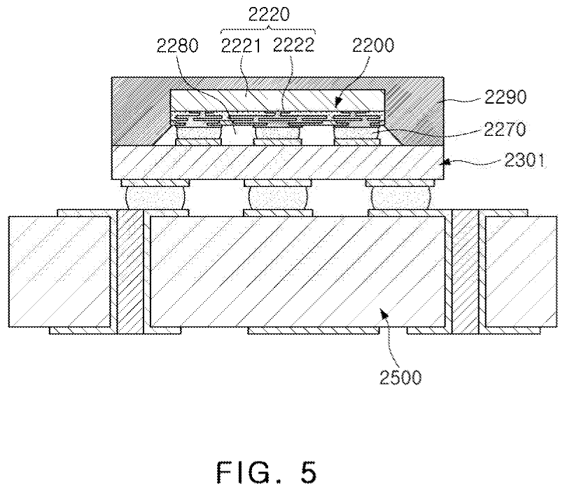

FIG. 5 is a schematic cross-sectional diagram illustrating an example in which a fan-in semiconductor package is mounted on a printed circuit board and mounted on a mainboard of an electronic device.

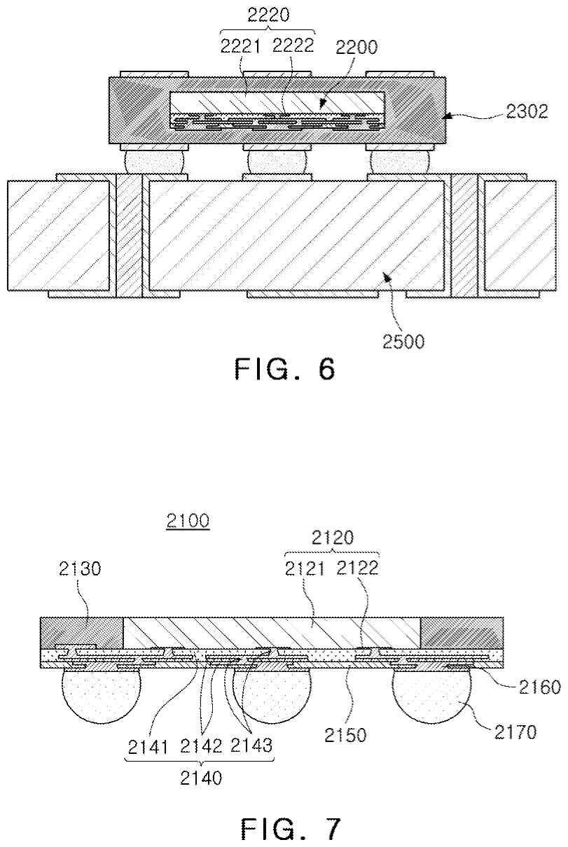

FIG. 6 is a schematic cross-sectional diagram illustrating an example in which a fan-in semiconductor package is mounted in a printed circuit board and mounted on a mainboard of an electronic device.

Referring to FIGS. 5 and 6, in a fan-in semiconductor package 2200, connection pads 2222, that is, I/O terminals, of a semiconductor chip 2220 may be redistributed through a BGA substrate 2301, and the fan-in semiconductor package 2200 may be ultimately mounted on a mainboard 2500 of an electronic device in a state in which it is mounted on the BGA substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate BGA substrate 2302, connection pads 2222, that is, I/O terminals, of the semiconductor chip 2220 may be redistributed by the BGA substrate 2302 in a state in which the fan-in semiconductor package 2200 is embedded in the BGA substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate BGA substrate and be then mounted on the mainboard of the electronic device through a packaging process or may be mounted and used on the mainboard of the electronic device in a state in which it is embedded in the BGA substrate.

Fan-Out Semiconductor Package

FIG. 7 is a schematic cross-sectional diagram illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case in which a size of the semiconductor chip is decreased, a standardized ball layout may be used in the fan-out semiconductor package as it is, such that the fan-out semiconductor package may be mounted on the mainboard of the electronic device without using a separate BGA substrate, as described below.

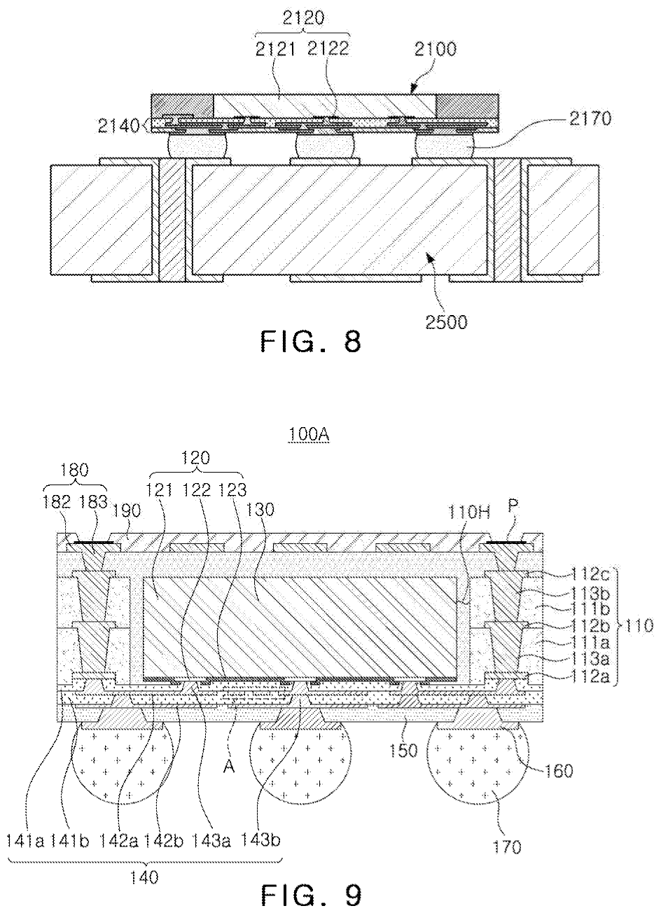

FIG. 8 is a schematic cross-sectional diagram illustrating an example in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate BGA substrate, or the like.

As described above, since the fan-out semiconductor package may be mounted on the mainboard of the electronic device without using the separate BGA substrate, the fan-out semiconductor package may be implemented at a thickness lower than that of the fan-in semiconductor package using the BGA substrate. Therefore, the fan-out semiconductor package may be miniaturized and thinned. In addition, the fan-out electronic component package has excellent thermal characteristics and electrical characteristics, such that it is particularly appropriate for a mobile product. Therefore, the fan-out electronic component package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as a BGA substrate, or the like, having a scale, a purpose, and the like, different from those of the fan-out semiconductor package, and having the fan-in semiconductor package embedded therein.

In the description below, a semiconductor package capable of controlling undulation even when a coating method is applied when manufacturing an interconnect structure, a redistribution region of a semiconductor package, will be described with reference to the drawings.

FIG. 9 is a schematic cross-sectional diagram illustrating an example of a semiconductor package.

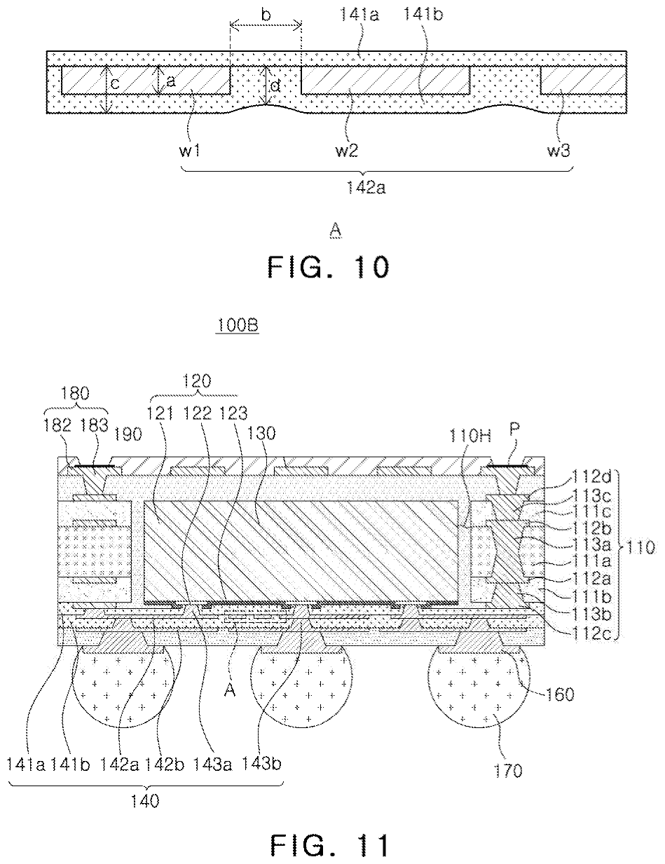

FIG. 10 is an enlarged schematic cross-sectional diagram illustrating region A illustrated in FIG. 9.

Referring to the drawings, a semiconductor package 100A in the example embodiment may include a semiconductor chip 120 having a connection pad 122, an encapsulant 130 covering at least a portion of the semiconductor chip 120, and an interconnect structure 140 disposed on the semiconductor chip 120 and the encapsulant 130. The interconnect structure 140 may include a first insulating layer 141a, a first redistribution layer 142a disposed on the first insulating layer 141a, and a second insulating layer 142b disposed on the first insulating layer 141a and covering the first redistribution layer 142a. The first redistribution layer 142a may include a plurality of patterns w1, w2, and w3 spaced apart from each other by a certain distance. When a thickness of the first redistribution layer 142a is a, a gap between a pattern w1 and a pattern w2 of the first redistribution layer 142a is b, b/a may be 4 or less.

A vacuum lamination process used in the process of manufacturing a printed circuit board may effectively resolve the issue of difference in thickness at different positions as an insulating layer is transited to a substrate through vacuum lamination when an insulating layer is formed, but it is highly likely that a void may be formed due to a defect caused by foreign objects created during cutting a film, and a defect in the filling of an insulating layer. Accordingly, in the field of a semiconductor package, a method of coating a substrate with a liquid insulating material has been used as a method of forming an insulating layer for forming a redistribution layer.

When the coating method is applied as a method for forming an insulating layer for forming a redistribution layer during a semiconductor package process, a substrate may be coated along a pattern shape, which may cause a difference between a thickness of an insulating layer in a region covering a pattern formed in advance on a substrate, and a thickness of an insulting layer between patterns, an undulation phenomenon. If the undulation increases, insulating reliability may degrade.

In the semiconductor package 100A in the example embodiment, when a thickness of the first redistribution layer 142a is a, a gap between the pattern w1 and the pattern w2 of the first redistribution layer 142a is b, b/a may be controlled to be 4 or less, and more preferably controlled to be 3 or less. The interconnect structure 140 may be manufactured to satisfy the above-described parameter. In this case, to form a fine circuit and to implement high density design, a photosensitive insulating material (a photo imageable dielectric, (PID)) may be used as a material of the first and second insulating layer 141a and 141b, such that, even when the coating method is applied, a difference between a thickness of a region of the second insulating layer 142b covering the first redistribution layer 142a and a thickness of a region of the second insulating layer 142b between the pattern w1 and the pattern w2 of the first redistribution layer 142a may be significantly reduced, and undulation may be controlled. Thus, when a sum of a thickness of a region of the second insulating layer 142b covering the first redistribution layer 142a and a thickness of the first redistribution layer 142a covered by such a region of the second insulating layer 141b is c, and a thickness of a region of the second insulating layer 142b between the pattern w1 and the pattern w2 of the first redistribution layer 142a is d, (c−d)/c may be 0.5 or less, more preferably 0.3 or less. In one example, d is the minimum thickness of the region of the second insulating layer 142b between the pattern w1 and the pattern w2 of the first redistribution layer 142a.

A value of b/a may be 0.1 or greater. Specifically, b/a may be 0.1 to 4, and may be 0.1 to 3 more preferably. When b/a is less than 0.1, a gap between the pattern w1 and the pattern w2 may be excessively reduced such that shorts may occur, or a thickness of the first redistribution layer 142a may excessively increase such that it may be difficult to implement a fine circuit and a high density design.

The thickness a of the first redistribution layer 142a may be 10 μm or less, and may be 0.5 μm to 10 μm, or 1 μm to 10 μm, for example. When a thickness of the first redistribution layer 142a exceeds 10 μm, it may be difficult to implement a fine circuit and a high density design, and even when b/a is controlled to be 4 or less, it may be difficult to control (c−d)/c to be 0.5 or less, which may cause undulation. When the thickness a of the first redistribution layer 142a is less than 1 μm or less than 0.5 μm, which is excessively thin, the first redistribution layer 142a may not properly perform the wiring, and open circuits may easily occur.

The gap b between the pattern w1 and the pattern w2 of the first redistribution layer 142a may be 40 μm or less, and may be around 0.1 μm to 40 μm, or 0.5 μm to 40 μm, for example. When the gap b between the pattern w1 and the pattern w2 of the first redistribution layer 142a, exceeds 40 μm, it may be difficult to control b/a to be 4 or less, and it may also be difficult to control (c−d)/c to be 0.5 or less, which may cause undulation. When the gap b between the pattern w1 and the pattern w2 of the first redistribution layer 142a is less than 0.5 μm, or is less than 0.1 μm, the gap between the pattern w1 and the pattern w2 may be excessively reduced such that shorts may occur.

When a sum of a thickness of a region of a second insulating layer 141b covering the first redistribution layer 142a and a thickness of the first redistribution layer 142a covered by such a region of the second insulating layer 141b is c, (c−a)/a may be 0.5 or greater, and may be 0.5 to 1.5, for example. When (c−a)/a is less than 0.5, a thickness of a region of the second insulating layer 141b covering the first redistribution layer 142a may be excessively thin such that it may be difficult to secure an insulating distance between the first and second redistribution layers 142a and 1 42b . Also, even when b/a is controlled to be 4 or less, it may be difficult to control (c−d)/c to be 0.5 or less, which may cause undulation. When (c−a)/a exceeds 1.5, a thickness of the second insulating layer 141b may excessively increase such that it may be difficult to reduce a size of the interconnect structure 140, and thus, it may be difficult to apply the configuration to a redistribution design of the semiconductor package. Similarly, the thickness c of a region of the second insulating layer 141b covering the first redistribution layer 142a may be 20 μm or less, and may be 1 μm to 20 μm, or 2 μm to 20 μm, for example.

In the description below, the elements included in the semiconductor package 100A will be described in greater detail.

A frame 110 may be an additional element. The frame 110 may improve stiffness of the semiconductor package 100A depending on a specific material of built-up layers 111a and 111b, and may secure uniformity of a thickness of the encapsulant 130. The frame 110 may have a through-hole 110H penetrating the built-up layers 111a and 111b. The semiconductor chip 120 may be disposed in the through-hole 110H, and a passive component (not illustrated) may also be disposed if desired. A wall of the through-hole 110H may be configured to surround the semiconductor chip 120, but an example embodiment thereof is not limited thereto. The frame 110 may further include wiring layers 112a, 112b, and 112c and wiring vias 113a and 113b in addition to the built-up layers 111a and 111b, and may thus work as an interconnect structure. The wiring layers 112a, 112b, and 112c and the wiring vias 113a and 113b may work as electrical interconnect members. If desired, a different form of an interconnect structure having an electrical interconnect member which may provide an upper/lower electrical connection path may be disposed instead of the frame 110.

The frame 110 may include a first built-up layer 111a in contact with the interconnect structure 140, a first wiring layer 112a in contact with the interconnect structure 140 and buried in the first built-up layer 111a, a second wiring layer 112b disposed in a portion of the first built-up layer 111a opposing a portion in which the first wiring layer 112a is buried, a second built-up layer 111b disposed on the first built-up layer 111a and covering at least a portion of the second wiring layer 112b, and a third wiring layer 112c disposed on a portion of the second built-up layer 111b opposing a portion in which the second wiring layer 112b is buried. The first and second wiring layers 112a and 112b and the second and third wiring layers 112b and 112c may be electrically connected to each other through the first and second wiring vias 113a and 113b respectively penetrating the first and second built-up layers 111a and 111b. The first to third wiring layers 112a, 112b, and 112c may be electrically connected to the connection pad 122 through the first redistribution layer 142a and/or the second redistribution layer 142b of the interconnect structure 140.

A material of the built-up layers 111a and 111b may not be limited to any particular material. For example, an insulating material may be used, and the insulating material may be a thermosetting resin such as an epoxy resin, a thermoplastic resin such as a polyimide resin, a resin in which the thermosetting resin or the thermoplastic resin is mixed with an inorganic filler, such as ajinomoto build-up film (ABF), or a resin in which the above-described resin is impregnated together with an inorganic filler in a core material as a glass fiber (or a glass cloth or a glass fabric), such as prepreg, for example.

The wiring layers 112a, 112b, and 112c may provide an upper/lower electrical connection path of the package along with the wiring vias 113a and 113b, and may redistribute the connection pads 122. As a material of the wiring layers 112a, 112b, and 112c, a metal material such as copper (Cu), aluminum (Al), silver (Ag), tin (Sn), gold (Au), nickel (Ni), lead (Pb), titanium (Ti), or alloys thereof may be used. The wiring layers 112a, 112b, and 112c may perform various functions depending on a design. For example, the redistribution layer 182 may include a ground (GrouND: GND) pattern, a power (PoWeR: PWR) pattern, a signal (Signal: S) pattern, and the like. The signal (S) pattern may include various signals other than a ground (GND) pattern, a power (PWR) pattern, and the like, such as a data signal. The redistribution layer 142 may also include a via pad, an electrical connector metal pad, and the like. The wiring layers 112a, 112b, and 112c may be formed by a well-known plating process, and each may include a seed layer and a conductor layer.

A thickness of each of the wiring layers 112a, 112b, and 112c may be greater than a thickness of each of the redistribution layers 142a and 142b. For example, the frame 110 may have a thickness greater than a thickness of the semiconductor chip 120, and a material of the built-up layers 111a and 111b may be pregreg to maintain stiffness, and thus, thicknesses of the wiring layers 112a, 112b, and 112c may be relatively great. A fine circuit and a high density design may be required for the interconnect structure 140, and thus, a material of the insulating layer 141a and 141b may be a photosensitive insulating material (PID). Accordingly, thicknesses of the redistribution layers 142a and 142b may be relatively reduced.

The first wiring layer 112a may be recessed into the first built-up layer 111a. As the first wiring layer 112a is recessed into the first built-up layer 111a, a stepped portion may be formed between a surface of the first built-up layer 111a in contact with the interconnect structure 140 and a surface of the first wiring layer 112a in contact with the interconnect structure 140, and accordingly, contamination of the first wiring layer 112a caused by bleeding of a formed material to the first wiring layer 112a may be prevented when the semiconductor chip 120 and the frame 110 are encapsulated using the encapsulant 130.

The wiring vias 113a and 113b may electrically connect the wiring layers 112a, 112b, and 112c formed on different layers, and may thus form an electrical path in the frame 110. As a material of the wiring vias 113a and 113b, a metal material such as copper (Cu), aluminum (Al), silver (Ag), tin (Sn), gold (Au), nickel (Ni), lead (Pb), titanium (Ti), or alloys thereof may be used. The wiring vias 113a and 113b each may be a filled type completely filled with a metal material, or may be a conformal type in which a metal material is formed along a side wall of a via hole. The wiring vias 113a and 113b each may have a tapered shape. The wiring vias 113a and 113b may be formed through a plating process, and may include a seed layer and a conductor layer.

When a hole for the first wiring via 113a is formed, a portion of a pad of the first wiring layer 112a may work as a stopper, and thus, the first wiring via 113a may be configured to have a tapered shape in which a width of a top surface is greater than a width of a bottom surface. In this case, the first wiring via 113a may be integrated with a pad pattern of the second wiring layer 112b. Also, when a hole for the second wiring via 113b is formed, a portion of a pad of the second wiring layer 112b may work as a stopper, and thus, the second wiring via 113b be configured to have a tapered shape in which a width of a top surface is greater than a width of a bottom surface. In this case, the second wiring via 113b may be integrated with a pad pattern of the third wiring layer 112c.

Although not illustrated, if desired, a metal layer (not illustrated) may be disposed on a wall of the through-hole 110H of the frame 110 to shield electromagnetic waves or to dissipate heat, and the metal layer (not illustrated) may surround the semiconductor chip 120.

The semiconductor chip 120 may be an integrated circuit (IC) in which several hundreds to several millions or more of devices are integrated in a single chip. The integrated circuit may be an application processor chip such as a central processor (for example, a central processing unit (CPU)), a graphics processor (for example, a graphics processing unit (GPU)), a digital signal processor, a cryptographic processor, a microprocessor, a microcontroller, or the like, but an example embodiment thereof is not limited thereto. The semiconductor chip 120 may be a power management integrated circuit (PMIC), a memory chip such as a volatile memory (for example, a dynamic random access memory (DRAM)), a non-volatile memory (for example, a read only memory (ROM)), a flash memory, or the like, or a logic chip such as an analog-to-digital (ADC) converter, an application-specific integrated circuit (ASIC), or the like.

The semiconductor chip 120 may be an integrated circuit in a bare state in which a bump or a wiring layer is not formed, but an example embodiment thereof is not limited thereto. If desired, the semiconductor chip 120 may be a packaged type integrated circuit. An integrated circuit may be formed based on an active wafer. In this case, a silicon (Si), germanium (Ge), gallium arsenide (GaAs), and the like, may be used as a base material of the body 121 of the semiconductor chip 120. The body 121 may include various circuits. The connection pad 122 may electrically connect the semiconductor chip 120 to other elements, and a metal material such as aluminum (Al), and the like, may be used as a material of the connection pad without any particular limitation. A passivation film 123 for opening the connection pad 122 may be formed on the body 121, and the passivation film 123 may be an oxide film or a nitride film, or may be a dual layer including an oxide layer and a nitride layer. An insulating film (not illustrated) may further be disposed in other desired positions. In the semiconductor chip 120, a surface on which the connection pad 122 is disposed may be an active surface, and an opposite surface may be an inactive surface. When the passivation film 123 is formed on the active surface of the semiconductor chip 120, the active surface of the semiconductor chip 120 may determine a positional relationship with reference to a lowermost surface of the passivation layer 123.

The encapsulant 130 may encapsulate the frame 110 and the semiconductor chip 120, and may fill a portion of the through-hole 110H. The encapsulant 130 may include an insulating material, and the insulating material may be a material including an inorganic filler and an insulating resin, such as a thermosetting resin such as an epoxy resin, a thermoplastic resin such as a polyimide resin, or a resin in which a reinforcement such as an inorganic filler is included in the above-described resins, such as an ABF, FR-4, BT, a resin, and the like, for example. Also, a molding material such as an EMC may be used, and a photosensitive material such as a photoimageable encapsulant (PIE) resin may be used if desired. Also, a resin in which an insulating resin such as a thermosetting resin or a thermoplastic resin is impregnated in a core material such as an inorganic filler and/or a glass fiber (or a glass cloth or a glass fabric), and the like, may be used.

The interconnect structure 140 may redistribute the connection pads 122 of the semiconductor chip 120. The several tens or several hundreds of connection pads 122 of the semiconductor chip 120 having various functions may be redistributed through the interconnect structure 140, and may be physically and/or electrically connected to an external entity through an electrical connector metal 170 in accordance with respective functions. The interconnect structure 140 may include the first insulating layer 141a, the first redistribution layer 142a disposed on the first insulating layer 141a, a first connection via 143a penetrating the first insulating layer 141a and electrically connecting the connection pad 122 to the first redistribution layer 142a, the second insulating layer 141b disposed on the first insulating layer 141a and covering the first redistribution layer 142a, the second insulating layer 142b disposed on the second insulating layer 141b, and a second connection via 143b penetrating the second insulating layer 141b and electrically connecting the first and second redistribution layers 142a and 142b. The number of each of the elements may be greater or less than the example illustrated in the diagram.

As a material of the insulating layer 141a and 141b, an insulating material may be used, and the insulating material may be a photosensitive insulating material (PID). In this case, a fine pitch may be included through a photo via, and thus, a fine circuit and a high density design may be implemented such that several tens to several millions of the connection pads 122 of the semiconductor chip 120 may be effectively redistributed. A boundary between the insulating layer 141a and 141b may be distinct or may be indistinct.

The redistribution layers 142a and 142b may redistribute the connection pads 122 of the semiconductor chip 120 and may electrically connect the connection pads 122 to the electrical connector metal 170. As a material of the redistribution layers 142a and 142b, a metal material such as copper (Cu), aluminum (Al), silver (Ag), tin (Sn), gold (Au), nickel (Ni), lead (Pb), titanium (Ti), or alloys thereof may be used. The redistribution layers 142a and 142b may perform various functions depending on a design. For example, the redistribution layer 182 may include a ground (GrouND: GND) pattern, a power (PoWeR: PWR) pattern, a signal (Signal: S) pattern, and the like. The signal (S) pattern may include various signals other than aground (GND) pattern, a power (PWR) pattern, and the like, such as a data signal. The redistribution layers 142a and 142b may also include a via pad, an electrical connector metal pad, and the like.

The connection vias 143a and 143b may electrically connect the redistribution layers 142a and 142b formed on different layers, and may electrically connect the connection pads 122 of the semiconductor chip 120 to the first redistribution layer 142a. The connection vias 143a may be physically in contact with the connection pads 122 when the semiconductor chip 120 is a bare die. As a material of the connection vias 143a and 143b, a metal material such as copper (Cu), aluminum (Al), silver (Ag), tin (Sn), gold (Au), nickel (Ni), lead (Pb), titanium (Ti), or alloys thereof may be used. The connection vias 143a and 143b each may be a filled type completely filled with a metal material, or may be a conformal type in which a metal material is formed along a side wall of a via hole. The connection vias 143a and 143b each may have tapered shapes, tapered in an opposite direction to a direction of the tapered shapes of the wiring vias 113a and 113b. The connection vias 143a and 143b may be formed through a plating process, and may include a seed layer and a conductor layer.

The passivation layer 150 may be an additional element for protecting the interconnect structure 140 from external physical and chemical damages, or the like. The passivation layer 150 may include a thermosetting region. For example, the passivation layer 150 may be an ABF, but a material of the passivation layer 150 is not limited thereto. The passivation layer 150 may have an opening 150h exposing at least a portion of the second redistribution layer 142b . Several tens to several thousands of the openings 150h may be provided, and the number of the openings 150h may be greater or less than the above example.

The under bump metal 160 may also be an additional element. The under bump metal 160 may improve connection reliability of the electrical connector metal 170, and may thus improve board-level reliability of the semiconductor package 100A. Several tens to several thousands of the under bump metals 160 may be provided, and the number of the under bump metals 160 may be greater or less than the above example. The under bump metals 160 each may be connected to the second redistribution layer 142b formed in the openings 150h. The under bump metal 160 may be formed by a well-known metallization method using a metal, but the method is not limited thereto.

The electrical connector metal 170 may also be an additional element, and may physically and/or electrically connect the semiconductor package 100A to an external entity. For example, the semiconductor package 100A may be mounted on a mainboard of an electronic device through the electrical connector metal 170. The electrical connector metal 170 may be formed of a metal having a low melting point, such as tin (Sn) or an alloy including tin (Sn), for example. For instance, the electrical connector metal 170 may be formed of a solder, but a material of the electrical connector metal 170 is not limited thereto.

The electrical connector metal 170 may be a land, a ball, a pin, or the like. The electrical connector metal 170 may be a plurality of layers or a single layer. When the electrical connector metal 170 includes a plurality of layers, the electrical connector metals 170 may include a copper pillar and a solder, and when the electrical connector metal 170 is a single layer, the electrical connector metal 170 may include a tin-silver solder or copper, but an example embodiment thereof is not limited thereto. The number of the electrical connector metals 170, a gap between the electrical connector metals 170, an arrangement form of the electrical connector metals 170 are not limited to any particular example, and may vary depending on a design. For example, the number of the electrical connector metals 170 may be several tens to several thousands depending on the number of the connection pads 122, or may be higher or lower than the above example.

At least one of the electrical connector metals 170 may be disposed in a fan-out region. The fan-out region may refer to a region beyond a region in which the semiconductor chip 120 is disposed. A fan-out package may have improved reliability as compared to a fan-in package, and a plurality of I/O terminals may be implement, and a 3D connection may easily be implemented in a fan-out package. Also, a fan-out package may have a reduced thickness, and may be cost-competitive as compared to a ball grid array (BGA) package, a land grid array (LGA) package, and the like.

A backside structure 180 may also be an additional element, and may be electrically connected to the connection pads 122 of the semiconductor chip 120. The backside structure 180 may include a backside redistribution layer 182 disposed on the encapsulant 130 and a backside connection via 183 penetrating the encapsulant 130 and electrically connecting the backside redistribution layer 182 to the third wiring layer 112c of the frame 110. If desired, an insulating layer (not illustrated) may further be included such that the backside redistribution layer 182 and the backside connection via 183 may include a plurality of layers.

The backside redistribution layer 182 may also include a metal material such as copper (Cu), aluminum (Al), silver (Ag), tin (Sn), gold (Au), nickel (Ni), lead (Pb), titanium (Ti), or alloys thereof. The backside redistribution layer 182 may perform various functions depending on a design. For example, the backside redistribution layer 182 may include a ground (GrouND: GND) pattern, a power (PoWeR: PWR) pattern, a signal (Signal: S) pattern, and the like. The signal (S) pattern may include various signals other than a ground (GND) pattern, a power (PWR) pattern, and the like, such as a data signal. The backside redistribution layer 182 may also include a via pad, a wire pad, an electrical connector metal pad, and the like.

The backside connection via 183 may electrically connect the backside redistribution layer 182 to the third wiring layer 112c. The backside connection via 183 may also include a metal material such as copper (Cu), aluminum (Al), silver (Ag), tin (Sn), gold (Au), nickel (Ni), lead (Pb), titanium (Ti), or alloys thereof. The backside connection via 183 may be a filled type completely filled with a metal material, or may be a conformal type in which a metal material is formed along a side wall of a via hole. The backside connection via 183 may have a tapered shape, tapered in the same direction as a direction of tapered shapes of the wiring vias 113a and 113b.

A cover layer 190 may be an additional element for protecting the backside structure 180 from external physical and chemical damages, and the like. The cover layer 190 may include a thermosetting resin. For example, the cover layer 190 may be formed of an ABF, but a material of the cover layer 190 is not limited thereto. The cover layer 190 may have an opening 190h for exposing at least a portion of the backside redistribution layer 182. Several tens to several thousands of the openings 190h may be provided, and the number of the openings 190h may be greater or less than the above example. A surface processing layer P may be formed on a surface of the backside redistribution layer 182 opened by the opening 190h if desired, and the surface processing layer P may be a well-known plating layer formed of a metal such as nickel (Ni)/gold(Au).

FIG. 11 is a schematic diagram illustrating another example of a semiconductor package.

Referring to the diagram, in a fan-out semiconductor package 100B in the example embodiment, a different form of a frame 110 may be included, as compared to the fan-out semiconductor package 100A described in the aforementioned example embodiment. For example, the frame 110 may include a core layer 111a, a first wiring layer 112a and a second wiring layer 112b disposed on both surfaces of the core layer 111a, a first built-up layer 111b and a second built-up layer 111c disposed on both surfaces of the core layer 111a, respectively, and covering the first and second wiring layers 112a and 112b, respectively, a third wiring layer 112c disposed on a portion of the first built-up layer 111b opposing a portion in which the first wiring layer 112a is buried, a fourth wiring layer 112d disposed on a portion of the second built-up layer 111c opposing a portion in which the second wiring layer 112b is buried, a first wiring via 113a penetrating the core layer 111a and electrically connecting the first and second wiring layers 112a and 112b, a second wiring via 113b penetrating the first built-up layer 111b and electrically connecting the first and third wiring layers 112a and 113c, and a third wiring via 113c penetrating the second built-up layer 111c and electrically connecting the second and fourth wiring layers 112b and 112d. As the frame 110 includes a greater number of the wiring layers 112a, 112b, 112c, and 112d, the interconnect structure 140 may further be simplified.

The core layer 111a may have a thickness greater than thicknesses of the first built-up layer 111b and the second built-up layer 111c. The core layer 111a may have a relatively great thickness to maintain stiffness, and the first built-up layer 111b and the second built-up layer 111c may be included to form a greater number of the wiring layers 112c and 112d. Similarly, the first wiring via 113a penetrating the core layer 111a may have a height and a diameter greater than heights and diameters of the second and third wiring vias 113b and 113c penetrating the second and third built-up layers 111b and 111c. Also, the first wiring via 113a may have an hourglass shape or a cylindrical shape, whereas the second and third wiring vias 113b and 113c may have tapered shapes, tapered in opposite directions. A thickness of each of the wiring layers 112a, 112b, 112c, and 112d may be greater than thicknesses of redistribution layers 142a and 142b.

In the fan-out semiconductor package 100B, a design for controlling undulation may also be applied to the interconnect structure 140, and the descriptions of the other elements, including the description of region A of the interconnect structure 140, are the same as the descriptions of the fan-out semiconductor package 100A described in the aforementioned example embodiment, and thus, the detailed descriptions thereof will not be repeated.

### EXAMPLE

An undulation control test was conducted while changing parameter conditions for region A of the above-described fan-out semiconductor packages 100A and 100B, and results of the test are listed in Table 1. In table 1 below, in the “Undulation Control,” “o” indicates an example in which (c−d)/c is 0.5 or less, and an undulation issue rarely occurred when the interconnect structure 140 was configured to include a plurality of layers, and “X” indicates an example in which (c−d)/c exceeds 0.5, and defects occurred due to undulation when the interconnect structures 140 was configured to include a plurality of layers.

TABLE 1

| | [a], | [b], | [c], | [c − a], | | [(c − a)/ | Undulation |
|---|---|---|---|---|---|---|---|
| Classification | μm | μm | μm | μm | [b/a] | a] | Control |
| Example 1 | 6 | 12 | 9 | 3 | 2 | 0.5 | ∘ |
| Example 2 | 6 | 18 | 9 | 3 | 3 | 0.5 | ∘ |
| Example 3 | 6 | 18 | 12 | 6 | 3 | 1 | ∘ |
| Example 4 | 6 | 24 | 12 | 6 | 4 | 1 | ∘ |
| Example 5 | 10 | 10 | 15 | 5 | 1 | 0.5 | ∘ |
| Example 6 | 10 | 20 | 15 | 5 | 2 | 0.5 | ∘ |
| Example 7 | 10 | 40 | 15 | 5 | 4 | 0.5 | ∘ |
| Example 8 | 10 | 10 | 20 | 10 | 1 | 1 | ∘ |
| Example 9 | 10 | 20 | 20 | 10 | 2 | 1 | ∘ |
| Example 10 | 10 | 40 | 20 | 10 | 4 | 1 | ∘ |
| Example 11 | 6 | 30 | 9 | 3 | 5 | 0.5 | x |
| Example 12 | 10 | 60 | 14 | 4 | 6 | 0.4 | x |
| Example 13 | 10 | 60 | 15 | 5 | 6 | 0.5 | x |
| Example 14 | 6 | 84 | 12 | 6 | 14 | 1 | x |
| Example 15 | 6 | 18 | 8 | 2 | 3 | 0.33 | x |
| Example 16 | 11 | 44 | 17 | 6 | 4 | 0.55 | x |

As indicated in Examples 1 to 10, when b/a was 4 or less, a was 10 μm or less, and (c−a)/a was 0.5 or greater, undulation was effectively controlled as (c−d)/c was 0.5 or less. Also, as indicated in Examples 11 to 14, when b/a exceeded 4, it was difficult to control undulation. Also, as indicated in Example 15, even when b/a was 4 less, when (c−a)/a was less than 0.5, c−a was excessively reduced as compared to b, and thus, it was difficult to control undulation. Also, as indicated in Example 16, even when b/a was 4 or less, when a exceeds 10 μm, it was difficult to control undulation.

According to the aforementioned example embodiments, a semiconductor package capable of controlling undulation even when a coating method is applied when manufacturing an interconnect structure, a redistribution region of a semiconductor package, may be provided.

In the example embodiments, the terms “lower side,” “lower portion,” “lower surface,” and the like, may be used to refer to directions facing downwardly with reference to a cross-section in the diagrams for ease of description, and the terms “upper side,” “upper portion,” “upper surfaces,” and the like, may be used to refer to directions opposing the above directions. The terms may be defined as above for ease of description, and the scope of right of the example embodiments is not particularly limited to the above terms.

In the example embodiments, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

In the example embodiments, the term “example embodiment” may not refer to one same example embodiment, but may be provided to describe and emphasize different unique features of each example embodiment. The above suggested example embodiments may be implemented do not exclude the possibilities of combination with features of other example embodiments. For example, even though the features described in one example embodiment are not described in the other example embodiment, the description may be understood as relevant to the other example embodiment unless otherwise indicated.

The terms used in the example embodiments are used to simply describe an example embodiment, and are not intended to limit the present disclosure. A singular term includes a plural form unless otherwise indicated.

While the example embodiments have been shown and described above, it will be apparent to those skilled in the art that modifications and variations could be made without departing from the scope of the present invention as defined by the appended claims.

What is claimed is:

1. A semiconductor package, comprising:
a semiconductor chip having a connection pad;
an encapsulant covering at least a portion of the semiconductor chip; and
an interconnect structure disposed on the semiconductor chip and the encapsulant,
wherein the interconnect structure includes a first insulating layer, a first redistribution layer disposed on the first insulating layer, and a second insulating layer disposed on the first insulating layer and covering the first redistribution layer,
wherein the first redistribution layer is electrically connected to the connection pad, and
wherein b/a is 4 or less, in which a is thickness of the first redistribution layer, and b is a gap between patterns of the first redistribution layer.

2. The semiconductor package of claim 1, wherein b/a is 0.1 or greater.

3. The semiconductor package of claim 1, wherein a is 10 μm or less.

4. The semiconductor package of claim 3, wherein a is 0.5 μm or greater.

5. The semiconductor package of claim 4, wherein b is 0.1 μm to 40 μm.

6. The semiconductor package of claim 1, wherein (c−a)/a is 0.5 or greater, in which c is a sum of a thickness of the second insulating layer in a region covering the first redistribution layer and a thickness of the first redistribution layer covered by the region of the second insulating layer.

7. The semiconductor package of claim 6, wherein (c−a)/a is 1.5 or less.

8. The semiconductor package of claim 7, wherein c is 1 μm to 20 μm.

9. The semiconductor package of claim 1, wherein the first redistribution layer includes copper (Cu).

10. The semiconductor package of claim 1, wherein the second insulating layer includes a photosensitive insulating material (PID).

11. The semiconductor package of claim 1, wherein a sum of a thickness of the second insulating layer in a region covering the first redistribution layer and a thickness of the first redistribution layer covered by the region of the second insulating layer is greater than a thickness of the second insulating layer in a region between patterns of the first redistribution layer.

12. The semiconductor package of claim 11, wherein (c−d)/c is 0.5 or less, in which c is the sum of the thickness of the second insulating layer in the region covering the first redistribution layer and the thickness of the first redistribution layer covered by the region of the second insulating layer, and d is the thickness of the second insulating layer in the region between the patterns of the first redistribution layer.

13. The semiconductor package of claim 1, wherein the interconnect structure further includes a second redistribution layer disposed on the second insulating layer.

14. The semiconductor package of claim 1, further comprising:
a frame having a through-hole,
wherein the semiconductor chip is disposed in the through-hole, and
wherein the encapsulant fills at least a portion of the through-hole.

15. The semiconductor package of claim 14,
wherein the frame includes a first built-up layer in contact with the first insulating layer, a first wiring layer in contact with the first insulating layer and buried in the first built-up layer, a second wiring layer disposed on a portion of the first built-up layer opposing a portion in which the first wiring layer is buried, a second built-up layer disposed on the first built-up layer and covering the second wiring layer, and a third wiring layer disposed on a portion of the second built-up layer opposing a portion in which the second wiring layer is buried, and
wherein the first to third wiring layers are electrically connected to the connection pad.

16. The semiconductor package of claim 14,
wherein the frame further includes a core layer, first and second wiring layers disposed on both surfaces of the core layer, respectively, first and second built-up layers disposed on both surfaces of the core layer, respectively, and covering the first and second wiring layers, respectively, a third wiring layer disposed on a portion of the first built-up layer opposing a portion in which the first wiring layer is buried, and a fourth wiring layer disposed on a portion of the second built-up layer opposing a portion in which the second wiring layer is buried, and
wherein the first to fourth wiring layers are electrically connected to the connection pad.
